(19) United States
(12) Patent Application Publication
(10) Pub. No.: US 2002/0096723 A1
(43) Pub. Date: Jul. 25, 2002

(54) Transient frequency in dynamic threshold metal-oxide-semiconductor field effect transistors

(76) Inventor: Kaoru Awaka, Tsukuba (JP)

Correspondence Address: TEXAS INSTRUMENTS INCORPORATED, P O BOX 655474, M/S 3999, DALLAS, TX, 75265

(21) Appl. No.: 09/732,249

(22) Filed: Dec. 7, 2000

Related U.S. Application Data
(60) Provisional application No. 60/174,102, filed on Dec. 31, 1999.

(51) Int. Cl. H01L 23/62; H01L 31/062; H01L 31/119

(52) U.S. Cl. 257/360; 257/369

(57) ABSTRACT

An integrated circuit having a primary transistor (12, 22, 32, 42, 52) and an associated secondary transistor (15, 25, 35, 45, 55) for dynamically varying the voltage of the body node (B) of the primary transistor (12, 22, 32, 42, 52) responsive to the gate voltage of the primary transistor (12, 22, 32, 42, 52) is disclosed. According to the disclosed embodiments of the invention, each of the primary transistor (12, 22, 32, 42, 52) and secondary transistor (15, 25, 35, 45, 55) are bulk transistors, formed at a surface of a substrate (11), where the secondary transistor (15, 25, 35, 45, 55) has a much smaller channel width than that of the primary transistor (12, 22, 32, 42, 52), to enhance the transient frequency of the device. In each case, the secondary transistor (15, 25, 35, 45, 55) has its source-drain path connected between the gate (G) and the body node (B) of the primary transistor (12, 22, 32, 42, 52). According to some embodiments of the invention, the secondary transistors (15, 25) have their gates biased to a bias voltage corresponding to their conductivity type. According to other embodiments, the gate of the secondary transistor (35, 45, 55) is connected to one end of its source-drain path. The disclosed arrangements provide good on-state performance while minimizing off-state source-drain leakage, and maintaining excellent transient frequency performance.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

This invention is in the field of integrated circuits, and is more specifically directed to the construction of transistors therein.

As is apparent in the industry, an ever-increasing trend is toward the reduction of power dissipation of electronic integrated circuits. Power dissipation is of concern, of course, in connection with battery-powered portable electronic systems, such as portable computers, wireless telephones, personal digital assistants (PDAs), and the like, because reduction in the power dissipated by the integrated circuits will, of course, translate directly into prolonged battery life. Even in stationary systems, such as personal computers and workstations, reduction in power dissipation is of importance in order to reduce the necessary size of system power supplies, and also for thermal control of the system.

Another trend in the electronics industry is to increase the functionality and complexity of integrated circuit devices. This additional functionality and complexity has driven a continuing trend toward smaller physical feature sizes of active devices, to maintain a reasonable theoretical manufacturing yield (which relates to the wafer area affected by a given killing defect density). Smaller device feature sizes also reduce the manufacturing cost of integrated circuits not only by improving the theoretical manufacturing yield, but also by increasing the number of potentially functional integrated circuits per wafer.

In combination with these decreasing feature sizes, however, other physical parameters such as film thicknesses, conductor conductivity, and junction depths must also be scaled. A particularly sensitive film thickness is that of the gate dielectric in metal-oxide-semiconductor field effect transistors (MOSFETs), which is generally reduced in a scaled manner along with feature sizes such as transistor channel width. The reduction in this critical dielectric thickness requires that voltages applied across the thin dielectric layer be reduced, in order to avoid dielectric breakdown of this sensitive film.

In order to reduce power dissipation of the circuit, and also to maintain good reliability in the integrated circuit itself, therefore, a recent trend in the electronics industry is to reduce the power supply voltages used to bias and power integrated circuits. For example, nominal power supply voltages for integrated circuits have been reduced, over the last twenty years, from 12 volts to voltages on the order of 1 volt. These low power supply voltages have been used to power highly complex integrated circuit functions in extremely low power applications, including battery-powered portable systems such as wireless telephones, personal digital assistants (PDAs), and “notebook-sized” portable computers.

However, this reduction in the power supply voltage of an integrated circuit generally causes a reduction in the electrical performance of the circuit. This performance degradation, in MOSFET circuits, results from the maximum drain-to-source and gate-to-source voltages being closer to the threshold voltage than in circuits having higher available voltages based off of a higher power supply voltage. As such, manufacturers of integrated circuits that are to operate with reduced power supply voltages have typically reduced transistor threshold voltages, for example by way of ion implantation, so that higher transistor drive characteristics are achieved. However, this reduction in threshold voltage necessarily involves a higher amount of drain-to-source off-state leakage current. This leakage current is especially undesirable in complementary-MOS (CMOS) circuits, particularly those intended for use in battery-powered applications.

Accordingly, conventional CMOS electronic circuits incorporate transistors having a relatively high standard threshold voltage, in order to avoid excessive drain-to-source leakage. The use of dual threshold voltages, to provide low threshold voltage transistors for high performance in combination with high threshold voltage transistors to block leakage, is known. However, the provision of dual threshold voltages adds significant manufacturing cost, considering that at least one additional masking step and one additional ion implantation operation is necessitated to provide dual threshold voltages.

By way of further background, FIG. 1 illustrates a conventional circuit configuration for digital MOSFET circuits, as used in low power supply voltage applications, and in which transistor threshold voltages are relatively low. This arrangement is referred to in the art as a dynamic threshold MOSFET (DT-MOSFET), and is used both in connection with bulk transistors, formed at a surface of a semiconductor substrate, and also in connection with silicon-on-insulator (SOI) transistors in which the body node and channels of the transistor are isolated from the underlying substrate by a dielectric layer. DT-MOSFET 2 of FIG. 1 is an n-channel device, and as such has its drain D receiving drain voltage V_{D}, which may range to as high as power supply voltage V_{dd}, and its source at source voltage V_{S}, which may be as low as ground. The dynamic threshold feature is implemented by way of a direct connection between gate G of transistor 2 and its body node 5; body node 5, as is well-known in the art, is the p-channel region located between and under the n-channel source S and drain D in this n-channel DT-MOSFET 2.

In operation, the connection between gate G and body node 5 in DT-MOSFET 2 biases body node 5 differently in the on and off digital states, such that the threshold voltage of transistor 2 differs in the on and off states and is in this sense “dynamc”. In the off state, with gate voltage V_{G} at a low voltage at or near the voltage Vₛ of source S, body node 5 will similarly be biased to a relatively low voltage, raising the threshold voltage of DT-MOSFET 2. In the on state, however, gate voltage V_{G} will be a relatively high voltage at or near the voltage V_{D} of drain D, in which case body node 5 will also be biased to this relatively high voltage, dropping the threshold voltage of DT-MOSFET 2. Accordingly, DT-MOSFET 2 has a high threshold voltage when off, thus reducing off-state drain-source leakage, but a low threshold voltage when on, thus providing good drive and fast switching performance.

The use of DT-MOSFET 2 in digital circuits is known, as discussed above. The industry has not heretofore utilized DT-MOSFET 2 in analog circuits, when implemented as a bulk transistor. The switching of the bias of body node 5 in DT-MOSFET 2 requires repeated charging and discharging of the parasitic capacitance 7 between body node 5 and source S upon each switching of the state of DT-MOSFET 2. Parasitic capacitance 7 is particularly sizable in bulk transistors, given the relatively large area of the p-n junction between body node 5 and its underlying substrate or well, to which source S is connected. Because capacitance 7 is connected to gate G, the transient frequency ∫ₜ of DT-MOSFET 2 would be greatly degraded by the charging and discharging of capacitance 7 during analog operation, especially at lower power supply voltages.

Additionally, it has been observed that DT-MOSFET 2 is not useful when used in circuits in which the power supply voltage V_{dd} is higher than the “cut-in” voltage of the p-n junction between body node 5 and source S. This limitation arises in the on-state, in which a voltage near power supply voltage V_{dd} is applied to gate G to fully drive DT-MOSFET 2, and driving body node 5 to power supply voltage V_{dd}. If power supply voltage V_{dd} is sufficiently high to forward bias the body-source junction, a large amount of leakage current from gate G to source S will result when DT-MOSFET 2 is on, causing power dissipation inefficiencies and also resulting in unexpectedly low input impedance for DT-MOSFET 2.

FIG. 2 illustrates another conventional implementation for SOI technologies, as described in Douseki, et al., “A 0.5V SIMOX-MTCMOS Circuit with 200ps Logic Gate”, Digest of Technical Papers, Int'l Solid State Circuits Conf. (IEEE, 1996), pp. 84-85. DT-MOSFET 2′ in the example of FIG. 2 is again an n-channel transistor, having source S at a source voltage V_{S} that may be as low as at ground and drain D at a drain voltage V_{D} that may be as high as power supply voltage V_{dd}; as described in the Douseki, et al. reference, DT-MOSFET 2′ is implemented in SOI technology, in which body node 5 is isolated from the substrate by a dielectric layer. In this conventional SOI implementation, n-channel transistor 8 has its source-drain path connected between gate G of DT-MOSFET 2′ and body node 5; the gate of transistor 8 is connected to body node 5. In effect, therefore, transistor 8 is biased in diode fashion, with its anode connected to body node 5 and its cathode at gate G. In this approach, transistor 8 places a reverse-biased diode between gate G and body node 5 when gate voltage V_{G} is driven high, limiting the leakage current that may be conducted from gate G to body node 5 to source S. The voltage of body node 5 in this example will be driven to a higher voltage with gate G driven high, however, by way of capacitive coupling, so that the dynamic threshold voltage modulation still takes place to some extent.

Of course, the SOI implementation of DT-MOSFET 2′ limits the parasitic capacitance of body node 5. While the Douseki et al. paper does not mention the use of DT-MOSFET 2′ in analog circuits, the SOI implementation described therein would preclude significant degradation of the transient frequency ∫_{T} were such an implementation used in an analog application. Furthermore, as is well-known in the art, the realization of integrated circuits according to SOI technology is extremely costly, particularly in producing the single-crystal active layer residing above the isolation dielectric film.

As such, modern electronic circuits continue to require the designer to choose between poor device performance at reduced power supply voltages and off-state drain-to-source leakage, if the high cost solution provided through dual threshold voltage transistors is to be avoided. Further, the lack of bulk device DT-MOSFET technology having sufficient transient frequency ∫_{T} has limited the applicability of dynamic threshold technology to analog circuits.

### BRIEF SUMMARY OF THE INVENTION

It is therefore an object of the present invention to provide a transistor implementation according to bulk device technology, having high drive performance at low power supply voltages, with low off-state leakage.

It is a further object of the present invention to provide such a transistor implementation that has relatively high transient frequency.

It is a further object of the present invention to provide such a transistor implementation that is particularly well-suited for analog circuit applications.

It is a further object of the present invention to provide such a transistor implementation that can achieve these benefits at little or no added manufacturing cost.

It is a further object of the present invention to provide such a transistor implementation in which the manufacturing process required for fabrication is not made unduly complicated.

Other objects and advantages of the present invention will be apparent to those of ordinary skill in the art having reference to the following specification together with its drawings.

The present invention may be implemented into a bulk technology integrated circuit, in which the body node of an MOS transistor is at a surface of a single crystal substrate. According to the present invention, a second transistor has its source-drain path connected between the gate and the body node of the MOS transistor, and has its gate biased in such a manner as to inhibit gate-to-body leakage in the MOS transistor. In this manner, dynamic threshold capability is provided in a manner that may be readily implemented in bulk devices.

### BRIEF DESCRIPTION OF THE SEVERAL VIEWS OF THE DRAWING

FIG. 1 is an electrical diagram, in schematic form, of a conventional MOS transistor arrangement.

FIG. 2 is an electrical diagram, in schematic form, of another conventional MOS transistor arrangement implemented in silicon-on-oxide (SO) technology.

FIG. 3a is an electrical diagram, in schematic form, of an MOS transistor arrangement according to a first preferred embodiment of the invention.

FIG. 3b is a schematic cross-sectional view of a portion of an integrated circuit illustrating the construction of the MOS transistor arrangement of FIG. 3a according to the first preferred embodiment of the invention.

FIG. 3c is a plan view of the portion of an integrated circuit illustrating the construction of the MOS transistor arrangement of FIG. 3a according to the first preferred embodiment of the invention.

FIG. 4a is an electrical diagram, in schematic form, of an MOS transistor arrangement according to a second preferred embodiment of the invention.

FIG. 4b is a schematic cross-sectional view of a portion of an integrated circuit illustrating the construction of the MOS transistor arrangement of FIG. 3a according to the second preferred embodiment of the invention.

FIG. 5 is an electrical diagram, in schematic form, of an MOS transistor arrangement according to a third preferred embodiment of the invention.

FIG. 6 is an electrical diagram, in schematic form, of an MOS transistor arrangement according to a fourth preferred embodiment of the invention.

FIG. 7 is an electrical diagram, in schematic form, of an MOS transistor arrangement according to a fifth preferred embodiment of the invention.

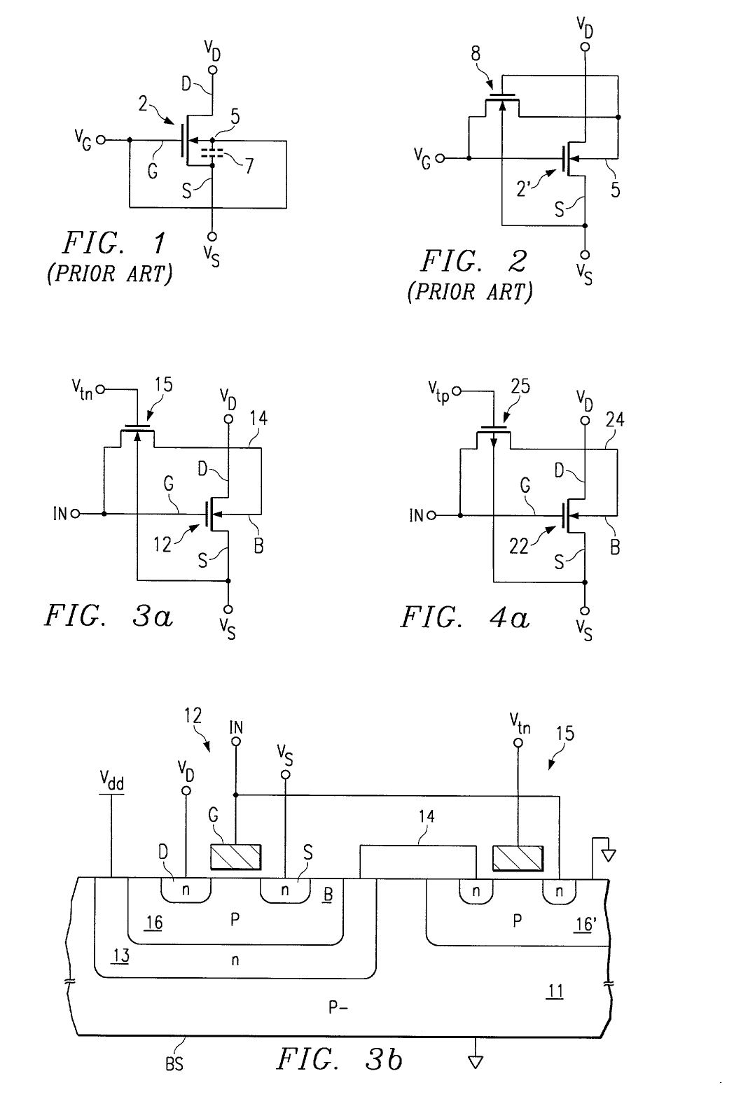

### DETAILED DESCRIPTION OF THE INVENTION

As will be apparent to those skilled in the art having reference to this specification, the present invention may be implemented in connection with a wide variety of technologies and circuit applications. More particularly, it will be appreciated from the following description that the present invention may be realized by way of n-channel metal oxide semiconductor (MOS), p-channel MOS, or complementary MOS (CMOS) technologies, as well as by way of combined MOS and bipolar technologies (referred to as “BiCMOS”). Additionally, the present invention as realized according to such technologies is particularly beneficial when incorporated into analog circuits or mixed-signal circuits; in some of the embodiments, the present invention is also useful in digital circuits. Accordingly, while the present invention will be described herein by way of several exemplary embodiments, it is to be understood that these embodiments are presented by way of example, and that such examples are not intended to limit the true scope of the present invention as hereinafter claimed.

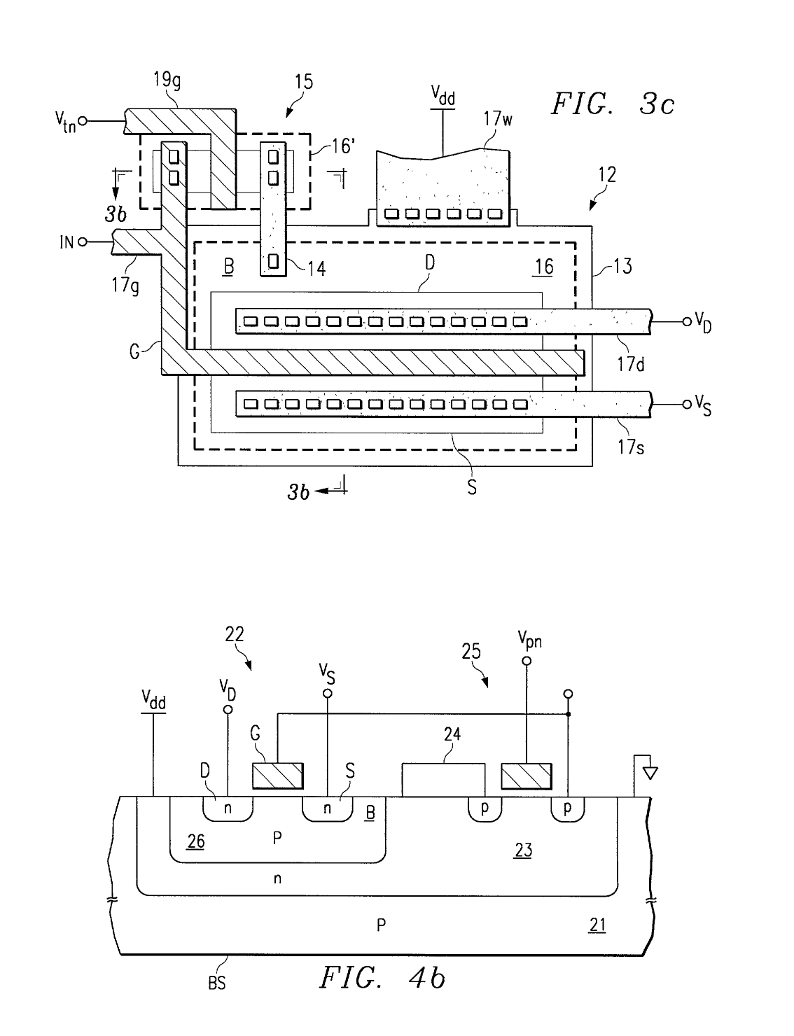

Referring now to FIG. 3a, a first preferred embodiment of the invention will now be described in connection with n-channel MOS transistor 12. As shown in FIG. 3a, transistor 12 has its drain D connected to receive a drain voltage V_{D} and its source S connected to receive a source voltage V_{S}; as is fundamental in the art, drain voltage V_{D} will generally be higher than source voltage V_{S}, as indicated by the selection of drain D and source S. The actual values of drain and source voltages V_{D}, V_{S} will, of course, depend upon the particular circuit configuration in which transistor 12 is implemented, as well as the level of the input signal on line IN that is applied to gate G of transistor 12. For example, when transistor 12 serves as an amplifier with a resistive load, source voltage V_{S} will be at ground and drain voltage V_{D} will serve as the output, pulled up toward power supply voltage V_{dd} by the load. In a CMOS inverter configuration, drain voltage V_{D} will again serve as an output voltage, but will be modulated according to conduction through a p-channel MOS transistor, reaching the full value of power supply voltage V_{dd} to drive a “1” logic level. Of course, other implementations of transistor 12 that perform other functions, such as a pass gate, open-drain drive transistor, and the like are known to those skilled in the art.

As shown in FIG. 3a, secondary transistor 15 is implemented in connection with transistor 12 to provide dynamic threshold voltage control according to this first preferred embodiment of the invention. Transistor 15 in this embodiment of the invention is an n-channel MOS transistor, having a source-drain path connected on one side to line IN at gate G of transistor 12, and connected on another end to body node B of transistor 12, by way of conductor 14; the body node of transistor 15 is biased to ground, for example by connection to source S of transistor 12. According to this embodiment of the invention, in which transistors 12, 15 are utilized in an analog circuit, the gate of transistor 15 is driven to a selected bias voltage Vₙ as used for biasing n-channel transistors elsewhere within the integrated circuit. Typically, bias voltage Vₙ will tend to be at least as high as the n-channel MOS threshold voltage Vₜₙ of transistor 15, and may be as high as the power supply voltage V_{dd}, but may also be as low as ground. For purposes of reduced settling time upon initialization and improved transient frequency in operation, bias voltage Vₙ is preferably as high as possible.

Alternatively, transistors 12, 15 may be utilized in a digital circuit. In this case, the gate voltage Vₙ is at a voltage at least as high as the lower of power supply voltage V_{dd} or the sum of n-channel MOS threshold voltage Vₜₙ of transistor 15 plus a diode cut-in voltage V_{cutin}.

According to the present invention, n-channel MOS transistor 12 is a bulk transistor, such that its source, drain, and body (i.e., channel) are implemented within a single crystal semiconductor body that is monolithic with the integrated circuit substrate, whether formed in an epitaxial layer grown at the surface of the substrate or simply by way of ion implantation or diffusion at a surface of the substrate without such epitaxy. Attention in this regard is directed to FIG. 3b, in which a cross-section of transistors 12, 15 according to this preferred embodiment of the present invention is schematically illustrated. It is contemplated that the following description will be sufficient to illustrate the construction of transistors 12, 15, and as such details such as doping concentrations, physical feature sizes, and the like will not be provided herein. Furthermore, it is to be understood that the size and location of the various features in FIG. 3a are not necessarily shown to scale.

FIG. 3b illustrates an exemplary arrangement of transistors 12, 15 as bulk transistors formed at a surface of p-type substrate 11, substrate 11 being a single-crystal body extending to its backside BS. It will, of course, be understood that the physical construction of transistors 12, 15 is presented herein by way of example only. In this example, n-well 13 is disposed at a portion of the surface of substrate 11, within which p-well 16 at the location of transistor 12 is disposed. Transistor 12 is formed within p-well 16, with n-well 13 isolating the body node of transistor 12 from substrate 11 so that the transistor body node voltage may be controlled by transistor 15. As such, heavily doped n-type drain region D and source region S are formed at the surface of p-well 16. The channel region of transistor 12 is located between drain region D and source region S, between which gate G is disposed, separated from the surface by a gate dielectric. As is typical in the art, gate G will typically be formed and patterned first, so that source region S and drain region D are self-aligned to gate G. In this exemplary construction, p-well 16 serves as the body node for transistor 12.

Transistor 15 is formed within p-well 16′, which is a doped region of similar depth and concentration as p-well 16, present at a nearby location of the surface of substrate 11. P-well 16′ is formed at a region of substrate 11 that does not include n-well 13. N-type source and drain regions of transistor 15 are formed within p-well 16′, on either side of gate electrode in conventional MOS fashion. P-well 16′ thus serves as the body node of transistor 15. Since the body node of transistor 15 is to be biased to ground (which is also the voltage to which substrate 11 is biased in this embodiment of the invention), the instance of p-well 16 at which transistor 15 is to be formed need not be isolated by n-well 13.

In the schematic cross-sectional view of FIG. 3b, the metal conductors by way of which signals and voltages are applied to transistors 12, 15 are not shown; rather, their presence and connections are simply shown in a schematic fashion. In this regard conductor 14 is illustrated in FIG. 3b as schematically connecting one end of the source-drain path of transistor 15 to body node B of transistor 12, consistently with the electrical schematic diagram of FIG. 3a.

FIG. 3c illustrates an exemplary layout of the arrangement of transistors 12, 15 according to this first preferred embodiment of the invention, at a surface of a semiconductor substrate 11. In this exemplary embodiment of the invention, transistor 12 is preferably much larger than transistor 15, considering that transistor 12 will generally be used to drive a downstream receiver of a signal or a load device; conversely, transistor 15 is only required to charge and discharge body node B of transistor 12, and as such need not be as large as transistor 12. In this embodiment of the invention, transistor 12 is formed as to have a relatively wide channel, with wide source region S and drain region D within well 16; current is conducted through the source-drain path of transistor 12 by way of metal conductors 17d, 17g, each of which make several contacts to their respective diffused regions D, S. Gate electrode 17g, which may be formed of polysilicon, refractory metal, metal silicide, or another conventional conductor material, extends the length of the distance across p-well 16 between source and drain regions S, D, to control source-drain conduction through transistor 12. N-well 13 is biased to power supply voltage V_{dd} by conductor 17w as shown in FIG. 3c; a ground bias is applied to substrate 11 by a conductor (not shown) or by backside contact.

Transistor 15, in this example, is a small transistor formed near transistor 12, but in its own p-well 16′. Gate electrode 17g makes contact (either directly, or alternatively by way of a metal strap) to one end of the source-drain region of transistor 15; the other end of this source-drain region is connected by conductor 14 to body node B within p-well 16, via contacts. Gate electrode 19g of transistor 15 is biased to bias voltage Vₙ, as schematically shown in FIG. 3c, to permit transistor 15 to properly control the voltage of body node B of transistor 12, as will now be described.

In operation, as noted above, drain voltage V_{D} will generally be higher than source voltage V_{S}, at least by the threshold voltage of transistor 15. Typically, for high drive performance, the voltage differential between drain voltage V_{D} and source voltage V_{S} will approach that between power supply voltage V_{dd} and ground. Also as noted above, the voltage applied to the gate of transistor 15 is bias voltage Vₙ which corresponds to a bias voltage used elsewhere in the integrated circuit in the biasing of n-channel transistors, and as such is conventionally set to a voltage that is at least as high as the threshold voltage of n-channel transistors, and may be as high as the power supply voltage V_{dd}, but may be as low as ground. This voltage Vₙ may be generated by a voltage divider, voltage regulator, bandgap reference voltage circuit, or some other conventional circuit elsewhere within the integrated circuit within which transistors 12, 15 are formed.

With the gate of transistor 15 at bias voltage Vₙ, transistor 15 will conduct according to its drain-to-source voltage as determined by line IN and body node B of transistor 12. For example, for an operating point where the voltage at line IN is somewhat high, to effect a high level of conduction through transistor 12, transistor 15 will conduct to such an extent to permit line IN to charge body node B of transistor 12 toward this higher voltage on line IN. This higher body node voltage will reduce the threshold voltage of transistor 12, enabling higher drive performance at this higher bias level.

Conversely, with line IN biased lower to cause relatively small conduction through transistor 12, transistor 15 will tend to discharge body node B of transistor 12 (and its parasitic capacitance), raising the threshold voltage of transistor 12 in this state; drain-source leakage of transistor 12 is thus reduced because of this higher threshold voltage. The body node voltage of transistor 12 may fall as low as the level of line IN, as transistor 15 remains on.

In this manner, secondary transistor 15 is able to modulate the voltage of the body node of drive transistor 12, and thus modulate its threshold voltage in a dynamic fashion so as to optimize its drive characteristics and minimize off-state leakage. This modulation is achieved in such a manner as to preclude leakage, despite the bulk implementation of transistors 12, 15.

Additionally, it has been observed, according to the present invention, that the transient frequency ∫_{T} is enhanced by the provision of secondary transistor 15 and its dynamic threshold voltage modulation, relative to the conventional single-transistor MOSFET case with the body node biased to ground (for n-channel MOS).

As is known in the art, transient frequency ∫_{T} may be approximated as:

$${f}_{T} = \frac{1}{2 π} \frac{{g}_{m} + {g}_{mbs}}{{C}_{gs} + {C}_{bs}}$$

where C_{gs} and C_{bs} are the gate-to-source and body-to-source capacitances, respectively, of transistor 12. The gain factors are defined as follows:

$${g}_{m} ≡ \frac{\partial {I}_{ds}}{\partial {V}_{gs}}$$

$${g}_{mbs} ≡ \frac{\partial {I}_{ds}}{\partial {V}_{bs}}$$

I_{ds} being the drain-to-source voltage, V_{gs} being the gate-to-source voltage, and V_{bs} being the body-to-source voltage, all of transistor 12. In the conventional case of an n-MOS transistor with its body node biased to ground, the parameters of g_{mbs} and C_{bs} are effectively insignificant because the body node is not coupled to the input node. In this instance, the expression for transient frequency ∫_{T} is approximated as:

$${f}_{T} \approx \frac{1}{2 π} \frac{{g}_{m}}{{C}_{gs}}$$

which is a well-known representation of transient frequency. Referring back to the conventional technique illustrated in FIG. 1, the effect of transconductance g_{mbs} becomes significant through coupling to the input node; however, the body-to-source capacitance C_{bs} presented as a result of the connection between the body node and gate node gives a large effect compared to that of gate-source capacitance C_{gs}. Since the latter effect overcomes the positive contribution from transconductance g_{mbs}, significant degradation of transient frequency ∫_{T} is observed, as discussed above.

According to the first preferred embodiment of the invention, however, secondary transistor 15 adds a series resistance that permits the positive contribution toward transient frequency ∫_{T} provided by transconductance g_{mbs} to overcome the negative effect of body-to-source capacitance C_{bs}. According to the configuration of FIGS. 3a through 3c, the effective body-to-source capacitance C_{bs-eff} is moderated from the body-to-source capacitance C_{bs} presented by transistors 12, 15 as follows:

$${C}_{bs - eff} = \frac{1}{\sqrt{{( 2 π {f}_{T} {R}_{ds} )}^{2} + \frac{1}{{C}_{bs}^{2}}}}$$

where R_{ds} represents the differential resistance of secondary transistor 15. This value C_{bs-eff} may thus be substituted into the definition of transient frequency ∫_{T} noted above. While transient frequency ∫_{T} may not be directly solvable therefrom, it is evident from the foregoing derivation of effective body-to-source capacitance C_{bs-eff} that the value of body-to-source capacitance that affects transient frequency ∫_{T} is significantly reduced, improving transient frequency ∫_{T} when the resistance presented by secondary transistor 15 is significant. The beneficial effect of differential resistance R_{ds} favors the fabrication of a relatively small transistor 15, such as is shown in FIG. 3c. In this regard, it has been observed, by simulation and in connection with the present invention, that a channel width of secondary transistor 15 that is on the order of one tenth the channel width of transistor 12, or smaller, will provide good dynamic threshold performance with improved transient frequency ∫_{T}, even with transistors 12,15 implemented as bulk transistors.

In this regard, it has been observed, by way of SPICE simulation, that the arrangement of FIGS. 3a through 3c according to this first preferred embodiment of the invention has greatly improved transient frequency ∫_{T} relative to the conventional approach described above relative to FIG. 1, and relative to the single MOSFET arrangement with body node at a fixed bias. For example, a simulated implementation of transistors 12, 15, where the channel width of transistor 12 is 30 μm and the channel width of transistor 15 is 0.3μm, exhibits transient frequency ∫_{T} of on the order of four to eight times that of a conventional nMOS device with its body node biased to ground, for bias conditions of V_{d}=Vₙ=0.6 volts and V_{S} at ground, and for input voltages on line IN between about 0.2 volts and 0.5 volts; as the voltage on line IN rises above 0.5 volts, the transient frequency ∫_{T} approaches that of the conventional arrangement, because transistor 15 essentially remains on in such a condition.

It should be especially noted that this excellent transient frequency ∫_{T} is obtained at very low drain voltage, below one volt. As such, the transistor arrangement according to this first preferred embodiment of the invention is well-suited for use in analog circuitry in integrated circuits biased by such low power supply voltages, and thus useful in connection with battery-powered portable electronic systems.

Furthermore, it has been observed, in connection with the present invention, that the inclusion of secondary transistor 15 according to this first preferred embodiment of the invention permits the operation of transistor 12 at relatively high input voltages. This benefit is provided by an effective voltage divider effect presented by secondary transistor 15, such that the voltage appearing at the body-to-source p-n junction of transistor 12 is reduced from that of conventional implementations such as shown in FIG. 1 and discussed hereinabove.

Referring now to FIGS. 4a and 4b, a second preferred embodiment of the present invention will now be described. As shown in FIG. 4a, this configuration includes n-channel MOS transistor 22, having its drain D at drain voltage V_{D}, its source S at source voltage V_{S}, and its gate G receiving the input signal from line IN. The body node B of transistor 22 is connected to one end of the source-drain path of p-channel secondary transistor 25 by conductor 24, while the other end of the source-drain path of transistor 25 is connected to line IN and thus to gate G of transistor 22. In this second preferred embodiment of the invention, the body node of transistor 25 is connected to power supply voltage V_{dd}. The gate of secondary transistor 25 is biased to a p-channel bias voltage Vₚ, which corresponds to a bias voltage applied to p-channel transistors in the CMOS integrated circuit containing transistors 22, 25. The bias voltage Vₚ should be at most at a voltage corresponding to the power supply voltage V_{dd} less the absolute value of the p-channel threshold voltage Vₜₚ of transistor 25. Again, in order to minimize the settling time of the circuit of transistors 22, 25 upon initialization, the voltage Vₚ should be as low as practicable; however, voltage Vₚ may be as high as power supply voltage V_{dd} without significantly degrading transient frequency ∫_{T}. Voltage Vₚ may be generated by a voltage divider, voltage regulator, bandgap reference circuit, or the like located within the integrated circuit containing transistors 22, 25.

The arrangement of transistors 22, 25 may also be used in a digital circuit. In a digital application, bias voltage Vₚ should be set to the higher of ground (0 volts) and the difference V_{dd}−V_{cutin}−|Vₜₚ|, where Vₜₚ is the p-channel threshold voltage of transistor 25.

As shown in FIG. 4b, transistors 22, 25 are bulk transistors, formed at a surface of substrate 21, either in a doped region of this surface or in an epitaxial semiconductor layer formed thereupon. Transistor 22 is formed similarly as transistor 12 described hereinabove relative to FIG. 3b, in that source S and drain D are diffused into p-well 26, which itself is formed within n-well 23 at a surface of substrate 21. As noted above, however, secondary transistor 25 in this embodiment of the invention is a p-channel device, and as such is formed by way of p-type diffused source/drain regions formed into a portion of n-well 23, as shown in FIG. 4b. The layout of transistors 22, 25 corresponds to that of transistors 12, 15 described hereinabove, again preferably with transistor 25 having a substantially smaller channel width than transistor 22, to minimize the effect of transistor 25 on the transient frequency ∫_{T} of transistor 22.

In operation, p-channel secondary transistor 25 operates in combination with transistor 22 in a similar manner as transistors 12, 15 described above. A high bias at line IN will tend to turn on transistor 22 to increase conduction therethrough. The combination of this input level with bias voltage Vₚ at the gate of transistor 25, causes transistor 25 to conduct to permit line IN to charge body node B of transistor 22 to a higher voltage (considering the voltage on line IN as the source of transistor 25 in this state). This higher body node voltage will, as before, reduce the threshold voltage of transistor 22 and increase its drive performance for signal variations around this high bias level on line IN. A lower bias presented at line IN, to reduce conduction through transistor 22, will cause transistor 25 to discharge body node B of transistor 22 and thereby elevate the threshold voltage of transistor 22, reducing the drain-source leakage of transistor 22.

In this manner, secondary transistor 25 also modulates the voltage of the body node of transistor 22 in a dynamic fashion, optimizing its drive characteristics while minimizing off-state leakage. Further, the transient frequency ∫_{T} of transistor 22 is improved relative to that of a single MOS transistor, particularly if the channel width of transistor 25 is kept relatively small relative to that of transistor 22. In connection with the present invention, SPICE simulation was performed for an arrangement of transistor 22 with channel width of 30 μm and transistor 25 with channel width of 0.3 μm. In this simulation, the arrangement of transistors 22, 25 exhibits transient frequency ∫_{T} of on the order of four to eight times that of a conventional n-MOS device with its body node biased to ground, for bias conditions of V_{d}=0.6 volts and V_{S}=Vₚ at 0 volts, and for input voltages on line IN between about 0.1 volts and 0.5 volts; again, as the voltage on line IN rises above 0.5 volts, the transient frequency ∫_{T} approaches that of the conventional arrangement, as transistor 25 essentially remains on in such a condition. This excellent performance is again achieved at relatively low power supply voltages.

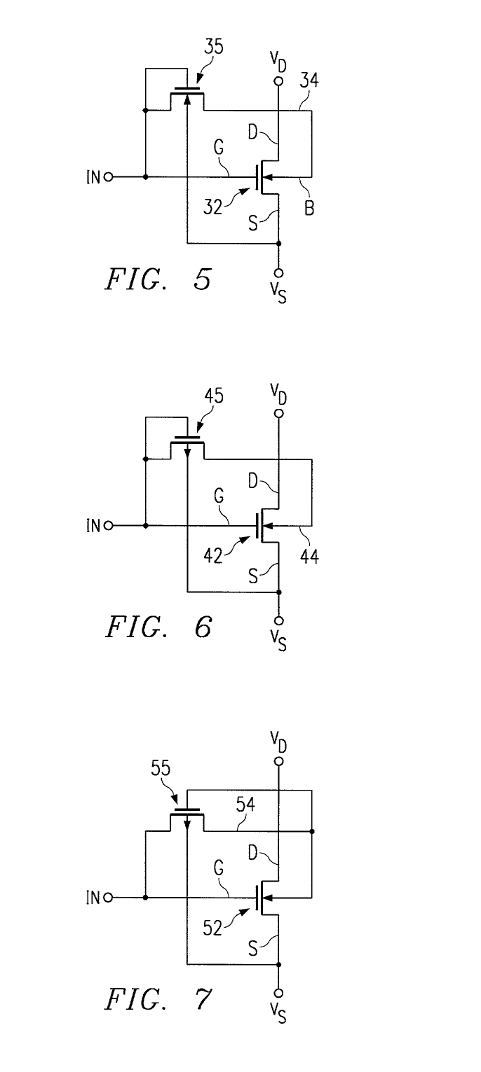

Referring now to FIG. 5, a MOS transistor according to a third preferred embodiment of the present invention will now be described. This configuration includes n-channel bulk MOS transistor 32 biased as in the previously-described embodiments, with drain D at drain voltage V_{D}, source S at source voltage V_{S}, and gate G connected to line IN. Body node B of transistor 32 is connected by conductor 34 to the source-drain path of n-channel secondary bulk transistor 35, and via transistor 35 to line IN and gate G of transistor 32; the body node of transistor 35 is biased to source voltage V_{S}. In this manner, the arrangement and construction of transistors 32, 35 is similar as transistors 12, 15 described hereinabove relative to FIGS. 3a through 3c, with the exception of the voltage to which the gate of transistor 35 is biased.

According to this third preferred embodiment of the invention, the gate of secondary transistor 35 is also connected to line IN, along with one end of the source-drain path of transistor 35. As such, transistor 35 will conduct so long as line IN is at a threshold voltage higher than body node B of transistor 32.

As noted above, transistors 32, 35 are bulk transistors, formed at doped regions of the surface of a semiconductor substrate, or in an epitaxial semiconductor layer formed thereupon. Transistors 32, 35 will be laid out, at the surface of this substrate, substantially as illustrated above relative to transistors 12, 15 described hereinabove, with the exception of the connection of the gate of transistor 35 to line IN. In this regard, for purposes of maintaining suitable transient frequency ∫_{T}, the channel width of transistor 35 is preferably kept relatively small relative to that of transistor 32.

In operation, a relatively high bias voltage on line IN will tend to turn on transistor 32 and, as noted above, cause secondary transistor 35 to conduct and charge body node B of transistor 32 to a higher voltage approaching that at line IN. This higher body node voltage will, as before, reduce the threshold voltage of transistor 32 and increase its drive performance. As noted above, transistor 35 is turned off as its drain-to-source voltage, which is the voltage differential between body node B and line IN, reaches the threshold voltage. In the case where the operating voltage of line IN is biased low to reduce conduction through transistor 32, the voltage of body node B will settle to a lower voltage, through diode leakage, thus raising the threshold voltage of transistor 32 in which case drain-source leakage is reduced.

According to this third preferred embodiment of the invention, secondary transistor 35 modulates the voltage of the body node of transistor 32 in a dynamic fashion, to provide improved drive characteristics for transistor 32 when on, while reducing its off-state leakage. These benefits are obtained in combination with enhancement of the transient frequency ∫_{T} of transistor 32.

Referring now to FIG. 6, a transistor arrangement according to a fourth preferred embodiment of the present invention will now be described. According to this embodiment of the invention, this configuration includes n-channel bulk MOS transistor 42 having its drain D at drain voltage V_{D}, source S at source voltage V_{S}, and its gate G connected to line IN. P-channel secondary bulk transistor 45 has its source-drain path connected between body node B of transistor 42, via conductor 44, to line IN and gate G of transistor 42, and has its body node biased to power supply voltage V_{dd}.

The arrangement and construction of transistors 42, 45 is similar as transistors 22, described hereinabove relative to FIGS. 4a and 4b, except that the gate of transistor 45 is connected to line IN. Transistors 42, 45 are bulk transistors, formed at doped regions of the surface of a semiconductor substrate, or in an epitaxial semiconductor layer formed thereupon, and laid out substantially as illustrated above relative to transistors 22, 25 described hereinabove. Again, the channel width of transistor 45 is preferably kept relatively small relative to that of transistor 42 to provide substantial enhancement of transient frequency ∫_{T}.

According to this fourth preferred embodiment of the invention, transistor 45 conducts when line IN is at a threshold voltage lower than that of body node B of transistor 42. In operation, therefore, a low operating point bias voltage at line IN, for reducing conduction through transistor 42, will turn on secondary transistor 45, discharging body node B of transistor 42 toward the lower voltage of line IN. This lower body node voltage will increase the threshold voltage of transistor 42 and reduce its source-drain leakage in this state. Transistor 45 is turned off as its drain-to-source voltage, which is the voltage differential between body node B and line IN, reaches the threshold voltage. Conversely, if the operating voltage of line IN is to be somewhat higher, so as to increase conduction through transistor 42, transistor 45 will be turned off; upon settling of the circuit to this operating condition, body node B will tend to float higher, raising the threshold voltage of transistor 42 and thus reducing leakage therethrough.

According to this fourth preferred embodiment of the invention, therefore, secondary transistor 45 dynamically modulates the voltage of the body node of transistor 42 to provide improved drive characteristics for transistor 42 while reducing source-drain leakage. These benefits are obtained in combination with substantial enhancement of the transient frequency ∫_{T} of transistor 42.

A fifth embodiment of the present invention is illustrated in FIG. 7. According to this embodiment of the invention, this configuration also includes n-channel bulk MOS transistor 52 having its drain D at drain voltage V_{D}, source S at source voltage V_{S}, and its gate G connected to line IN, as described before. P-channel secondary bulk transistor 55 has its source-drain path connected between body node B of transistor 52, via conductor 54, to line IN and gate G of transistor 52, and has its body node biased to power supply voltage V_{dd}.

The arrangement and construction of transistors 52, 55 is similar as transistors 42, 45 described hereinabove, but for the biasing of the gate of transistor 55 which, in this case, is connected to body node B of transistor 52. Transistors 52, 55 are again bulk transistors, formed at doped regions of the surface of a semiconductor substrate, or in an epitaxial semiconductor layer formed thereupon, and laid out substantially as described above relative to transistors 42, 45. The channel width of transistor 55 is preferably kept relatively small relative to that of transistor 52 to provide enhancement in the parameter of transient frequency ∫_{T}.

According to this fifth preferred embodiment of the invention, as noted above, the gate of transistor 55 is connected to the body node B of transistor 52, and thus transistor 55 conducts when line IN is at least a threshold voltage higher than that of body node B of transistor 52. In operation, therefore, a high operating bias at line IN will also turn on secondary transistor 55, charging body node B of transistor 52 toward this higher voltage at line IN. This higher body node voltage will decrease the threshold voltage of transistor 52 and as a result will improve its drive characteristics. This increase in the body node voltage of transistor 52 continues until transistor 55 is turned off upon the voltage differential between body node B and line IN reaching the threshold voltage of transistor 55. Conversely, a lower operating bias at line IN will not turn transistor 55 on; upon settling of the circuit to this bias condition, through diode leakage and the like, body node B of transistor 52 will drop, thus raising the threshold voltage of transistor 52 and reducing leakage therethrough.

According to this fifth preferred embodiment of the invention, therefore, secondary transistor 55 also dynamically modulates the voltage of the body node of transistor 52, thus improving the drive characteristics of transistor 42, and reducing its off-state source-drain leakage. These benefits are obtained in combination with significant enhancement of the transient frequency ∫_{T} of transistor 52.

With regard to each of the embodiments of the present invention illustrated in FIGS. 5 through 7, it is noted above that the body node of the primary transistor 32, 42, 52 settles to a particular voltage when secondary transistors 35, 45, 55 are turned off. This settling time may be improved by the provision of a small shorting transistor in parallel with secondary transistors 35, 45, 55, controlled to short the source and drain of the associated secondary transistor and thus discharge the body node; of course, some small amount of additional complexity will result from the provision of such a shorting device.

It is contemplated that further alternative realizations of the present invention will be apparent to those skilled in the art having reference to this specification. For example, each of the above-described embodiments utilize an n-channel drive transistor; the present invention may be realized using a p-channel drive transistor, through the use of complementary doping schemes relative to those shown and described hereinabove. Other alternative realizations, such as those involving the combination of the described transistor arrangements in connection with other transistors, including according to a CMOS or other technology, are also contemplated herein.

According to the present invention, as described above, numerous important advantages are provided, particularly in analog circuits realized in bulk technology. According to the present invention, excellent drive performance is obtained while maintaining low off-state leakage levels, even at low power supply voltages. The transient frequency ∫_{T} of these transistor arrangements is enhanced while obtaining this dynamic threshold voltage control, according to the present invention; indeed, this improved transient frequency ∫_{T} is provided even at low power supply voltages. Further, the advantages of the present invention are obtained through the use of standard threshold voltage devices, and do not require the provision of dual threshold voltages; as a result, the present invention involves little additional manufacturing cost over conventional approaches, especially considering that the secondary transistors utilized according to the present invention are preferably relatively small in relation to their associated primary devices.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

I claim:

1. An integrated circuit, comprising:
a primary field-effect transistor formed in a surface of a semiconductor substrate, having a source-drain path, a gate, and a body node of a first conductivity type; and
a secondary field-effect transistor formed in the surface of the semiconductor substrate, having a source-drain path connected on one end to the gate of the primary transistor and connected on another end to the body node of the primary transistor, the secondary transistor having a gate biased so that the voltage of the body node of the primary transistor is higher when the gate of the primary transistor is at a voltage that turns on the primary transistor than when the gate of the primary transistor is at a voltage that turns off the primary transistor.

2. The integrated circuit of claim 1, wherein the body node of the secondary transistor is of the first conductivity type.

3. The integrated circuit of claim 1, wherein the body node of the secondary transistor is of a second conductivity type, opposite that of the first conductivity type.

4. The integrated circuit of claim 1, wherein the secondary transistor has a body node connected to a power supply voltage.

5. The integrated circuit of claim 1, wherein the gate of the secondary transistor is connected to one end of its source-drain path.

6. The integrated circuit of claim 5, wherein the body node of the secondary transistor is of the first conductivity type;
and wherein the gate of the secondary transistor is connected to the end of its source-drain path connected to the gate of the primary transistor.

7. The integrated circuit of claim 5, wherein the body node of the secondary transistor is of a second conductivity type, opposite that of the first conductivity type.

8. The integrated circuit of claim 1, wherein the substrate is of the first conductivity type;
and further comprising:
a well, of a second conductivity type, opposite that of the first conductivity type, surrounding the body node of the primary transistor, to provide junction isolation of the body node of the primary transistor from the substrate.

9. The integrated circuit of claim 1, wherein the primary transistor has a channel width that is substantially larger than a channel width of the secondary transistor.

10. An integrated circuit, comprising:
a primary field-effect transistor formed in a surface of a semiconductor substrate, and having a source, a drain, a gate, and a body node of a first conductivity type;
a secondary field-effect transistor formed in a surface of a semiconductor substrate, and having a source-drain path connected on one end to the gate of the primary transistor and connected on another end to the body node of the primary transistor, the secondary transistor having a gate biased to a bias voltage corresponding to its conductivity type.

11. The integrated circuit of claim 10, wherein the body node of the secondary transistor is of the first conductivity type.

12. The integrated circuit of claim 10, wherein the body node of the secondary transistor is of a second conductivity type, opposite that of the first conductivity type.

13. The integrated circuit of claim 10, wherein the secondary transistor has a body node connected to a power supply voltage.

14. The integrated circuit of claim 10, wherein the primary and secondary transistors are disposed near a surface of a substrate that is of the first conductivity type;
and further comprising:
a well, of a second conductivity type, opposite that of the first conductivity type, surrounding the body node of the primary transistor, to provide junction isolation of the body node of the primary transistor from the substrate.

15. The integrated circuit of claim 10, wherein the primary transistor has a channel width that is substantially larger than a channel width of the secondary transistor.
